(19) United States
(12) Patent Application Publication
(10) Pub. No.: US 2015/0201530 A1
(43) Pub. Date: Jul. 16, 2015

(54) Heat Spreading Packaging Apparatus

(71) Applicant: PHIHONG TECHNOLOGY CO., LTD., Taoyuan County (TW)

(72) Inventors: Pi-Ming LIU, Taipei City (TW); Hung-Chih SHIH, Taoyuan City (TW)

(73) Assignee: PHIHONG TECHNOLOGY CO., LTD., Taoyuan County (TW)

(21) Appl. No.: 14/292,515

(22) Filed: May 30, 2014

(30) Foreign Application Priority Data
Jan. 14, 2014 (TW) 103101295

(51) Int. Cl. H05K 7/20; H04M 1/11; F21V 29/83

(52) U.S. Cl. CPC H05K 7/20445; F21V 29/83; H04M 1/11

(57) ABSTRACT

This invention is related to a new heat spreading packaging design and the constituting method, especially mounting a heat spreader into an electronic device, so that it can reduce the internal temperature of device and make uniform surface temperature effectively.

### TECHNICAL FIELD

The present invention generally relates to a new heat spreading packaging design and assembling method, especially mounting a heat spreader into an electronic device, so that it can reduce the internal temperature of device and make uniform surface temperature effectively.

### BACKGROUND

In recent years, current electronic devices is towards miniaturization, thinner, and multiple functions, resulting in increasing current and consumption of power of an electronic component, and the higher local temperature of electronic component. Thus, heat dissipation requirement of electronic device has become greatly emphasized.

Conventional cooling technology is setting heat medium disposed between electronic components and heat sink. The heat medium is for example, thermal silica films, thermal paste, thermal-sided tape or the like, conducting heat generated by the electronic component to the heat sink, in order to achieve the purpose of cooling. Heat energy generated heat source is conducted via heat medium to housing of electronic device through thermal convection, radiation or other heat conduction and further dissipating heat to outside of the device. Conventional cooling device generally has a larger surface area to enhance the cooling efficiency. Materials used as a heat sink can be divided into two kinds of metal and non-metal, such as copper, ceramics. Metal, such as copper, has excellent thermal conductivity. However, electrical conductivity of metal limits its occupation region of metal heat sink, due to electromagnetic interference created by metal in the electronic device. In addition, metal layer needs to have some thickness for a better cooling effect, so it results in a requirement of spatial arrangement of metal layer. Non-metallic heat sink can reduce electromagnetic interference to the device, but it creates a higher cost of manufacturing.

The above conventional cooling technology, heat medium is used to conduct thermal energy generated by electronic components to heat sink and housing of electronic device, and then through thermal convection for cooling. However, to reach the insulation effect, housing of electronic device is generally made of low thermal conductivity material, and therefore heat is not evenly distributed on the housing for dissipating. As heat sink is not allowed in electronic device due to limited space, it is not easy to achieve the expected cooling effect.

### SUMMARY OF THE INVENTION

As mentioned above, heat medium is used to conduct thermal energy generated by electronic components to heat sink and housing of electronic device, and then through thermal convection for cooling. That is, heat sink (cooling fin) is embedded in the electronic device for thermal dissipating, or thin type heat sink is disposed on the electronic device for thermal dissipating. Therefore, such heat sink occupied a specified space in the device can not meet the requirement of miniaturization of device.

To solve this problem, the invention provides a new heat spreading packaging structure. A thermally conductive heat sink is embedded in housing of the electronic device, so that heat generated during operation of electronic components can be removed by the thermally conductive heat sink to improve the cooling effect and uniform surface temperature of the housing. Elements of heat spreading packaging are engaged to each other, and separable with each other. So, adhesive is not used when engaged. Furthermore, the thermally conductive heat sink is embedded into the housing without occupying the internal space of electronic device. Therefore, the present invention can be applied to high power devices or compact portable devices, and effectively improve heat dissipating efficiency of high power device or compact portable devices.

According to an aspect of the invention, it proposes a heat spreading packaging apparatus applied to an electronic device, the heat spreading packaging apparatus comprising a housing, at least one holding member, engaged with the housing, and at least one heat spreader for spreading heat energy form internal electronic components of the electronic device to outside of the electronic device, wherein the at least one heat spreader is sandwiched in between the at least one holding member and the housing. The at least one heat spreader is sandwiched in between the holding member and the housing for fully isolating form the electronic components. At least one holding member is contacting with partial of the at least one heat spreader, and the at least one heat spreader contacting with at least one of the internal electronic components.

In an aspect, the housing has at least one hole or aperture such that the at least one heat spreader is partially isolated from outside of the electronic device, wherein the at least one hole or aperture has longitudinal shape, round shape, curved shape or a combination thereof.

In another aspect, the holding member has at least one hole or aperture, wherein the at least one hole or aperture has longitudinal shape, round shape, curved shape or a combination thereof. The heat spreader is a sheet, curved, cylindrical shape or a combination thereof The heat spreader is fully isolated form the electronic components

In yet another aspect, the electronic device is a mobile cell phone or LED (light emitting diode) bulb.

In one aspect, the housing and the holding member are made of an insulating material. Material of said heat spreader includes metal, graphite, graphene, carbon nanotubes, carbon fibers, diamond-like carbon composite material of high thermal conductivity, high thermal conductivity of silicon composition, high thermal conductivity materials, or a combination thereof.

### BRIEF DESCRIPTION OF THE DRAWINGS

The components, characteristics and advantages of the present invention may be understood by the detailed descriptions of the preferred embodiments outlined in the specification and the drawings attached:

FIG. 1 illustrates a heat spreading packaging apparatus according to the first embodiment of the invention;

FIG. 1A illustrates a cross-sectional view of the heat spreading packaging apparatus of FIG. 1;

FIG. 1B illustrates a cross-sectional view of the heat spreading packaging apparatus according to another embodiment of the invention;

FIG. 1C illustrates a cross-sectional view of the heat spreading packaging apparatus according to yet another embodiment of the invention;

FIG. 2 illustrates a heat spreading packaging apparatus applied to a mobile cell phone according to one embodiment of the invention;

FIG. 3 illustrates a heat spreading packaging apparatus applied to LED (light emitting diode) bulb according to one embodiment of the invention;

FIG. 4 illustrates a heat spreading packaging apparatus applied to a mobile cell phone according to another embodiment of the invention;

FIG. 5 illustrates a heat spreading packaging apparatus applied to LED (light emitting diode) bulb according to another embodiment of the invention;

FIG. 6 illustrates a heat spreading packaging apparatus applied to a mobile cell phone according to yet another embodiment of the invention; and

FIG. 7 illustrates a heat spreading packaging apparatus applied to LED (light emitting diode) bulb according to yet another embodiment of the invention.

### DETAILED DESCRIPTION

Reference will now be made in detail to several embodiments, examples of which are illustrated in the accompanying figures. It is noted that wherever practicable similar or like reference numbers may be used in the figures and may indicate similar or like functionality. The figures and accompanying description depict various embodiments for purposes of illustration only. One skilled in the art will readily recognize from the following description that alternative embodiments of the structures and methods illustrated herein may be employed without departing from the principles described herein.

The invention discloses a heat spreading packaging apparatus applied to electronic devices. The heat spreader is configured (fixed to) onto the interlayer and embedded into housing of the electronic devices. The heat spreader is directly or in-directly contacting with the heat source such that heat energy is directed to outside of the electronic devices, in order to achieve the purpose for improving cooling effects and make surface of the housing in effective average temperature.

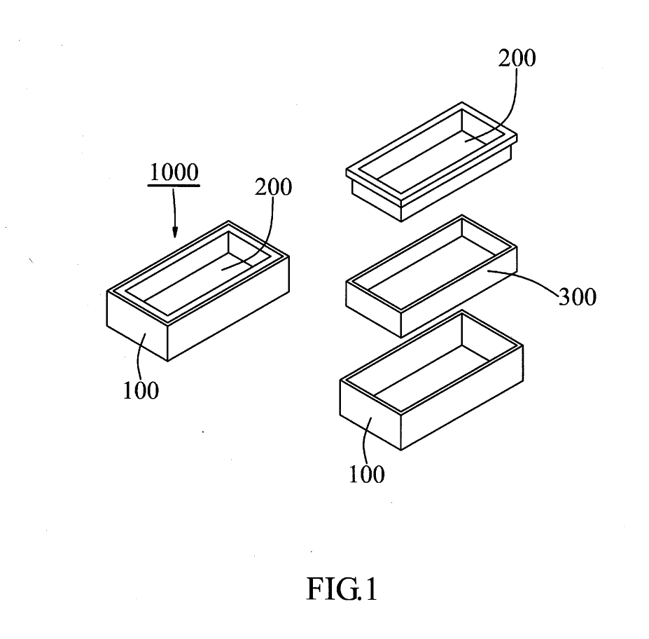

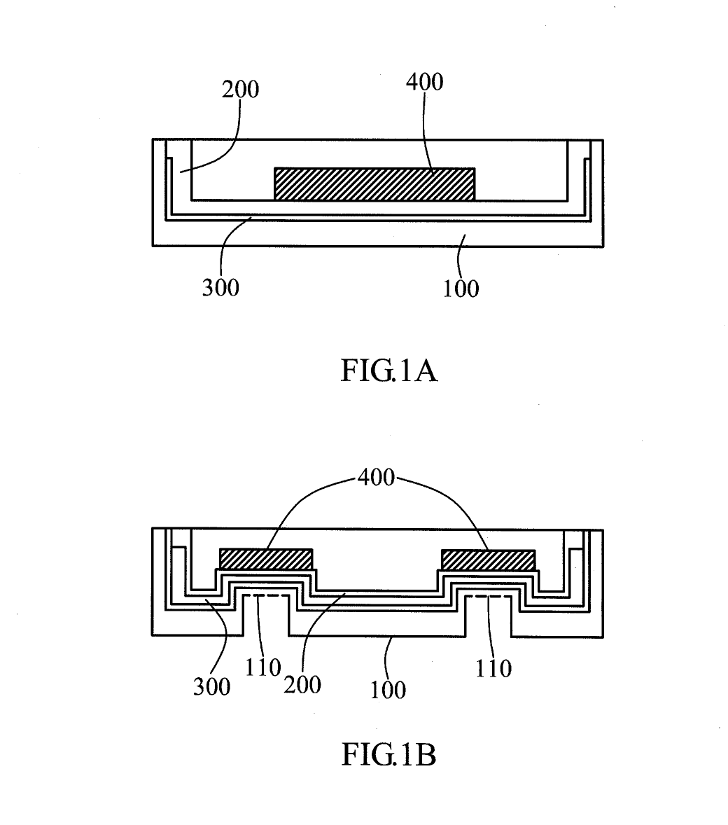

FIG. 1 illustrates a heat spreading packaging apparatus of one embodiment of the invention. As shown in FIG. 1, the heat spreading packaging apparatus 1000 includes a housing (enclosure) 100, which is equipped with a thermally conductive heat spreader (sink) 300 therein, and a holding member 200. The heat spreader 300 is configured (engaged) with the holding member 200, and the heat spreader 300 is sandwiched in between the holding member 200 and the housing 100. Components of the heat spreading packaging apparatus 1000 of the invention 1000 are engaged with each other mutually, so the components can be disassembled from each other, and without using adhesives or similar substitute materials for fixing there-between.

As noted above, the housing 100 refers to housing of the electronic device, such as mobile cell phone, high-power bulb. The housing is made of an insulating material. The holding member 200 is made of an insulating material. Material of the heat spreader 300 includes metal, graphite, graphene, carbon nanotubes, carbon fibers, diamond-like carbon composite material of high thermal conductivity, high thermal conductivity of silicon composition or other high thermal conductivity materials, or a combination thereof, and the heat spreader 300 may be a sheet, cylindrical, or any curved shape.

FIG. 1A illustrates a cross-sectional view of the heat spreading packaging apparatus of FIG. 1. As shown in FIG. 1A, the heat spreading packaging apparatus 1000 includes a housing (enclosure) 100, which is equipped with a thermally conductive heat spreader (sink) 300 therein, and a holding member 200. The heat spreader 300 is configured (engaged) with the holding member 200, and the heat spreader 300 is sandwiched (fixed) in between the holding member 200 and the housing 100 for fully isolating form the heat source (electronic components). The heat spreader 300 and the heat source 400 in the heat spreading packaging apparatus 1000 of the invention are isolated from outside of the heat spreading packaging apparatus 1000. The heat source 400 may be any electronic components capable of generating heat inside the electronic device, and not limited to large-area electronic components.

FIG. 1B illustrates a cross-sectional view of the heat spreading packaging apparatus according to another embodiment. As shown in FIG. 1B, the heat spreading packaging apparatus 1000 includes a housing (enclosure) 100 having at least one hole or aperture (aperture) 110 for heat energy more efficiently spreading to external environment through heat convection and heat radiation, which is equipped with a thermally conductive heat spreader (sink) 300 therein, and a holding member 200. Due to the housing 100 with hole or aperture 110, the heat spreader (sink) 300 is partially isolated from outside of the electronic device. The heat spreader 300 is configured (engaged) with the holding member 200, and the heat spreader 300 is sandwiched (fixed) in between the holding member 200 and the housing 100. The heat spreader 300 and the heat source 400 in the heat spreading packaging apparatus 1000 of the invention are isolated from outside of the heat spreading packaging apparatus 1000. The at least one hole or aperture 110 may be designed as longitudinal shape, round shape, any other curved shape or a combination thereof. The at least one hole or aperture 110 may be designed with the position of local heat source 400 in order to achieve the purpose of more efficient heat energy dissipation. The design of the hole or aperture 110 can meet all requirements of the standards of relevant safety regulations.

FIG. 1C illustrates a cross-sectional view of the heat spreading packaging apparatus according to yet another embodiment. As shown in FIG. 1 C, the heat spreading packaging apparatus 1000 includes a housing (enclosure) 100, which is equipped with a thermally conductive heat spreader (sink) 300 therein, and a holding member 200. The heat spreader 300 is configured (engaged) with the holding member 200, and the heat spreader 300 is sandwiched (fixed) in between the holding member 200 and the housing 100. The holding member 200 has at least one hole or aperture 210 such that the holding member 200 is contacting with partial of the heat spreader 300 for contacting with the heat source 400. The heat spreader 300 and the heat source 400 in the heat spreading packaging apparatus 1000 of the invention are isolated from outside of the heat spreading packaging apparatus 1000. The at least one hole or aperture 210 may be designed as longitudinal shape, round shape, any other curved shape or a combination thereof. The at least one hole or aperture 210 may be designed with the position of local heat source 400 in order to achieve the purpose of more efficient heat energy dissipation. The design of the hole or aperture 210 can meet all requirements of the standards of relevant safety regulations.

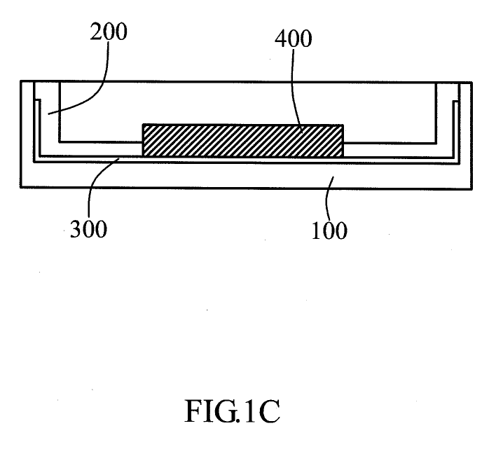

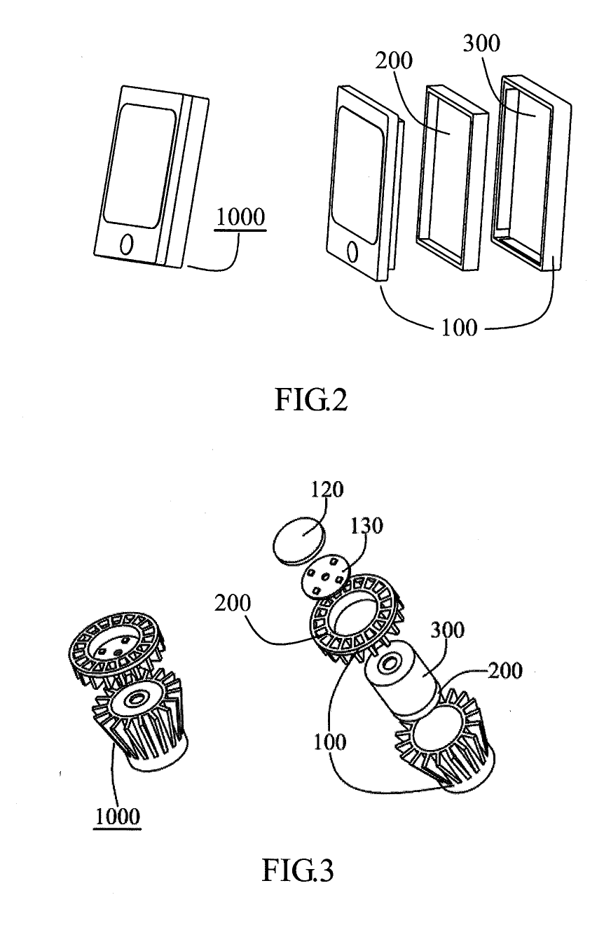

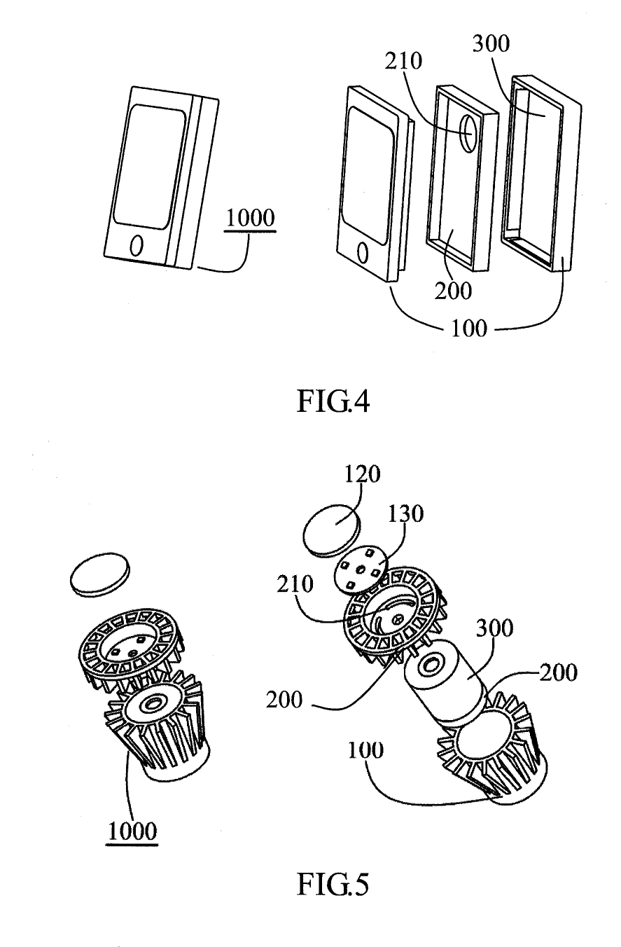

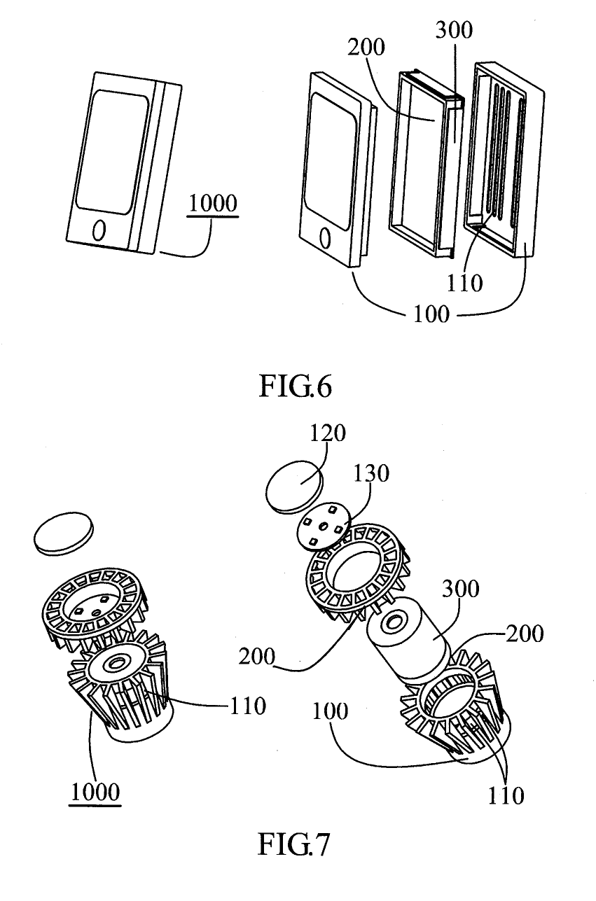

FIG. 2, FIG. 4 and FIG. 6 illustrate a heat spreading packaging apparatus applied to a mobile cell phone according to the embodiments of the invention. As shown in FIG. 2, the heat spreading packaging apparatus 1000 of mobile cell phone includes a housing (enclosure) 100, which is equipped with a thermally conductive heat spreader (sink) 300 therein, and a holding member 200. The heat spreader 300 is configured (engaged) with the holding member 200, and the heat spreader 300 is sandwiched (fixed) in between the holding member 200 and the housing 100. The holding member 200 is engaged with the housing 100 to constitute heat spreading packaging apparatus 1000 of the mobile cell phone such that electronic components in the mobile cell phone are isolated from external environment. As shown in FIG. 4, the holding member 200 further comprises at least one hole or aperture 210 for the heat spreader 300 partially contacting with the interior electronic components, and the electronic components in the heat spreading packaging apparatus 1000 of the invention are isolated from external environment. In another embodiment, as shown in FIG. 6, the housing (enclosure) 100 comprises at least one hole or aperture 110 for heat energy more efficiently spreading to external environment through heat convection and heat radiation. The above-mentioned hole or aperture 110 and the hole or aperture 210 may be designed as longitudinal shape, round shape, any other curved shape or a combination thereof. The heat spreader 300 is a sheet, curved, cylindrical shape or a combination thereof. The hole or aperture 110 and the hole or aperture 210 may be designed with the position of local electronic components in order to achieve the purpose of more efficient heat energy dissipation. The design of the hole or aperture 110 and the hole or aperture 210 can meet all requirements of the standards of relevant safety regulations.

FIG. 3, FIG. 5 and FIG. 7 illustrate a heat spreading packaging apparatus applied to LED (light emitting diode) bulb according to the embodiments of the invention. As shown in FIG. 3, the heat spreading packaging apparatus 1000 of LED bulb includes a transparent sheet 120, LED's packaging board 130, and a housing 100 which is equipped with a thermally conductive heat spreader (sink) 300 therein, and two holding members 200. The heat spreader 300 is configured (engaged) with the holding member 200, and the heat spreader 300 is sandwiched (fixed) in between the holding member 200 and the housing 100. The holding member 200 is engaged with the housing 100 to constitute heat spreading packaging apparatus 1000 of LED bulb such that electronic components in the LED bulb are isolated from external environment. As shown in FIG. 5, the holding member 200 further comprises at least one hole or aperture 210 for the heat spreader 300 partially contacting with the LED's packaging board 130, and the electronic components in the heat spreading packaging apparatus 1000 of the invention are isolated from external environment. In another embodiment, as shown in FIG. 7, the housing (enclosure) 100 comprises at least one hole or aperture 110 for heat energy more efficiently spreading to external environment through heat convection and heat radiation. The above-mentioned hole or aperture 110 and the hole or aperture 210 may be designed as longitudinal shape, round shape, any other curved shape or a combination thereof. The hole or aperture 110 and the hole or aperture 210 may be designed with the position of local electronic components in order to achieve the purpose of more efficient heat energy dissipation. The design of the hole or aperture 110 and the hole or aperture 210 can meet all requirements of the standards of relevant safety regulations.

The foregoing descriptions are preferred embodiments of the present invention. As is understood by a person skilled in the art, the aforementioned preferred embodiments of the present invention are illustrative of the present invention rather than limiting the present invention. The present invention is intended to cover various modifications and similar arrangements included within the spirit and scope of the appended claims, the scope of which should be accorded the broadest interpretation so as to encompass all such modifications and similar structures.

What is claimed is:

1. A heat spreading packaging apparatus applied to an electronic device, said heat spreading packaging apparatus comprising:
a housing;
at least one holding member, engaged with said housing; and
at least one heat spreader for spreading heat energy form internal electronic components of said electronic device to outside of said electronic device, wherein said at least one heat spreader is sandwiched in between said at least one holding member and said housing.

2. The apparatus of claim 1, wherein said at least one heat spreader is sandwiched in between said holding member and said housing for fully isolating form said electronic components.

3. The apparatus of claim 1, wherein said at least one holding member is contacting with partial of said at least one heat spreader, and said at least one heat spreader contacting with at least one of said internal electronic components.

4. The apparatus of claim 1, wherein said housing has at least one hole or aperture such that said at least one heat spreader is partially isolated from outside of said electronic device.

5. The apparatus of claim 4, wherein said at least one hole or aperture has longitudinal shape, round shape, curved shape or a combination thereof.

6. The apparatus of claim 1, wherein said holding member has at least one hole or aperture.

7. The apparatus of claim 6, wherein said at least one hole or aperture has longitudinal shape, round shape, curved shape or a combination thereof.

8. The apparatus of claim 1, wherein said heat spreader is a sheet, curved, cylindrical shape or a combination thereof.

9. The apparatus of claim 1, wherein said heat spreader is fully isolated form said electronic components.

10. The apparatus of claim 1, wherein said housing is made of an insulating material.

11. The apparatus of claim 1, wherein said holding member is made of an insulating material.

12. The apparatus of claim 1, wherein material of said heat spreader includes metal, graphite, graphene, carbon nanotubes, carbon fibers, diamond-like carbon composite material of high thermal conductivity, high thermal conductivity of silicon composition, high thermal conductivity materials, or a combination thereof.

13. The apparatus of claim 1, wherein said electronic device is a mobile cell phone.

14. The apparatus of claim 1, wherein said electronic device is a LED (light emitting diode) bulb.
